(19) United States
(12) Patent Application Publication
(10) Pub. No.: US 2016/0227961 A1
(43) Pub. Date: Aug. 11, 2016

(54) METHOD AND APPARATUS FOR SURFACE TREATMENT OF DISPOSABLE ROASTING PAN USING ATMOSPHERIC PLASMA, AND DISPOSABLE ROASTING PAN FABRICATED USING THE SAME METHOD

(71) Applicants: Changje Park, Changwon-si (KR); Sungran Mun, Changwon-si (KR)

(72) Inventors: Changje Park, Changwon-si (KR); Sungran Mun, Changwon-si (KR)

(21) Appl. No.: 14/748,340

(22) Filed: Jun. 24, 2015

(30) Foreign Application Priority Data
Feb. 5, 2015 (KR) 10-2015-0017756

(51) Int. Cl. A47J 37/06; C23C 16/56; C23C 16/50

(52) U.S. Cl. CPC A47J 37/06; C23C 16/50; C23C 16/56

(57) ABSTRACT

A method and apparatus for surface treatment of disposable roasting pan using atmospheric plasma, and a disposable roasting pan fabricated using the same method are disclosed herein. The apparatus for surface treatment of a disposable roasting pan using atmospheric plasma includes a conveyer belt, a discharge electrode, a plate-shaped ground electrode, first and second power lines, and a discharge space. The conveyer belt transfers an aluminum sheet base. The discharge electrode is disposed above the conveyer belt. The plate-shaped ground electrode is disposed below the conveyer belt. The first power line applies the (+) high voltage of a high-voltage power unit to the discharge electrode. The second power line applies the (−) high voltage of the high-voltage power unit to the ground electrode. The discharge space is forced in a space between the discharge electrode and the ground electrode.

### BACKGROUND

1. Technical Field

The embodiments of the present invention relate to a disposable roasting pan in which fins depressions and protrusions are formed on the surface of a roasting pan base, formed of an aluminum sheet or aluminum foil, by atmospheric plasma, and a method for the surface treatment of the disposable roasting pan.

2. Description of the Related Art

In general, when meat or fish is roasted, a metallic roasting pan made of brass or stainless steel, a Teflon-coated roasting pan coated with Teflon in the form of a film, or a ceramic roasting pan made of ceramic is used.

The metallic roasting pan is disadvantageous in that: a large quantify of substances harmful to the human body are generated, the nutrients of meat are destroyed because the meat sticks thereto or is burnt, smoke and smell are generated, there is the inconvenience of washing, drying and storing the roasting pan after usage, and environmental pollution is incurred due to detergent that is used to wash the roasting pan after usage.

The roasting pan coated with Teflon is disadvantageous in that a substance harmful to the human body is generated and the usage of the roasting pan is difficult because Teflon is peeled off.

The ceramic roasting pan is disadvantageous in that it is difficult to use the ceramic roasting pan because the ceramic roasting pan is heavy, it is inconvenient to wash the roasting pan, and it is difficult to deal with oil generated when meat is roasted.

Meanwhile, a conventional red clay roasting pan is disadvantageous in that: it is difficult to fabricate the red clay roasting pan, it is difficult to use the red clay roasting pan, the red clay roasting pan has low economic efficiency because the manufacturing cost thereof is high, the red clay roasting pan is inconvenient for outdoor usage because it is heavy and large, regardless of its advantage of repeated usage, and the red clay roasting pan incurs the inconvenience in which it should be stored after washing.

Related Art Documents

Patent Documents

Patent Document 1: Korean Patent No. 10-1218725 (entitled “Far-infrared Radiation Cooking Pan,” and published on Jan. 7, 2013)

Patent Document 2: Korean Patent No. 10-1398430 (entitled “Meat Roasting Pan,” and published on May 27, 2013)

Patent Document 1: Korean Patent No. 10-1328510 (entitled “Method of Manufacturing Meat Roasting Pan,” and published on Nov. 13, 2013)

### SUMMARY

An embodiment of the present invention is to provide a method for the surface treatment of a disposable roasting pan using atmospheric plasma, in which ultrafine depressions and protrusions are formed on the surface of a base (roasting pan base), formed of an aluminum sheet or aluminum foil, by atmospheric plasma, thereby enabling the surface coating of a red clay ceramic layer and the like to be considerably efficiently and easily performed.

Another embodiment of the present invention is to provide an apparatus for the surface treatment of a disposable roasting pan using atmospheric plasma.

Still another embodiment of the present invention is to provide a disposable roasting pan, which is fabricated for disposable use by a method for surface treatment using atmospheric plasma, which can be conveniently used and is used such that meat does not stick or is not burnt, the meat is not dehydrated, the texture of the meat is soft, and thus the unique flavor of the meat can be enjoyed because the meat is cooked by the action of far-infrared radiation.

In accordance with an aspect of the present invention, there is provided a method for surface treatment of a disposable roasting pan using atmospheric plasma, the method including the steps of: (a) preparing an aluminum sheet base having a thickness ranging from 30 to 100 μm; (b) forming fine depressions and protrusions on the surface of the aluminum sheet base by surface-treating the surface of the aluminum sheet base using atmospheric plasma; (c) coating the surface of the base on which the fine depressions and protrusions have been formed with a red clay ceramic liquid in which a red clay powder and a ceramic binder have been mixed together; (d) drying the base coated with the red clay ceramic liquid with hot air having a temperature of about 150° C. for a period ranging from 10 to 30 minutes.

The fine depressions and protrusions formed at step (b) may be ultrafine depressions and protrusions having a size of about 10 Å.

The red clay ceramic liquid used at step (c) may be formed by mixing the red clay powder and the ceramic binder having a thickness of about 1 μm at a weight ratio of 50:50 and then diluting the mixture with water for general use at a weight ratio of 50:50.

The red clay ceramic liquid used at step (c) may be applied to the surface of the base on which the fine depressions and protrusions have been formed to a thickness ranging from 10 to 20 μm.

In accordance with another aspect of the present invention, there is provided a disposable roasting pan fabricated by the method for surface treatment of a disposable roasting pan.

In accordance with still another aspect of the present invention, there is provided an apparatus for fabricating a disposable roasting pan, the apparatus including: a conveyer belt configured to transfer an aluminum sheet base; a discharge electrode disposed above the conveyer belt; a plate-shaped ground electrode disposed below the conveyer belt; a first power line configured to apply (+) high voltage of a high-voltage power unit to the discharge electrode; a second power line configured to apply (−) high voltage of the high-voltage power unit to the ground electrode; and a discharge space formed in a space between the discharge electrode and the ground electrode.

The discharge electrode may be fitted into an upwardly open groove formed in a lengthwise direction of a ceramic support; and the ceramic support may be connected to a support member by a plurality of insulating support rods and is supported by the plurality of insulating support rods.

The high voltage applied across the discharge electrode and the ground electrode may range from 8,000 V to 50,0000 V, a frequency may range from 10,000 Hz to 50,000 Hz, and a current may range from 5 A to 10 A.

The apparatus may further include an exhaust duct disposed in any one of an upper portion and a side portion of the discharge space and equipped with at last one exhaust fan.

In accordance with still another aspect of the present invention, there is provided an apparatus for surface treatment of a disposable roasting pan using atmospheric plasma, the apparatus including: a base wound around a pull-out roller located on one side of the apparatus; a take-up roller located on a remaining side of the apparatus, and configured to wind the base; a pulley disposed around the take-up roller; a pulley disposed around an axis of rotation of a drive motor; a belt configured to connect the two pulleys; a conveyer belt disposed between the pull-out roller and the take-up roller; an apparatus for atmospheric plasma surface treatment disposed above the conveyer belt; a coating unit located behind the apparatus for atmospheric plasma surface treatment; and a drying room located between the coating unit and the take-up roller.

The coating unit may include: a lower drum configured to support a bottom of the base; a coating drum configured to support a top of the base and to apply a red clay ceramic liquid; an auxiliary drum configured to operate in contact with the coating drum; and the red clay ceramic liquid configured to be supplied into a space above an interval between the coating drum and the auxiliary drum.

The drying room may include: a plurality of guide rollers disposed inside the drying room in a zigzag manner; heating means disposed in a lower portion of the drying room so that a temperature of about 150° C. is constantly maintained; and an entrance and an exit formed on both sides of the drying room.

In accordance with yet another aspect of the present invention, there is provided a disposable roasting pan fabricated by a method for surface treatment using atmospheric plasma, the disposable roasting pan including: an aluminum sheet base having a thickness ranging from 30 to 100 μm; a surface-treated portion configured such that fine depressions and protrusions having a size of about 10 Å are formed, on a surface of the aluminum sheet base by atmospheric plasma; and a red clay ceramic layer applied, dried and fixed onto the surface-treated portion to a thickness ranging from 10 to 20 μm.

The aluminum sheet base may be of a dish type.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a sectional view illustrating a disposable roasting pan 1 according to an embodiment of the present invention;

FIG. 2 is a front view illustrating the configuration of an apparatus for atmospheric plasma surface treatment according to an embodiment of the present invention;

FIG. 3 is a side view illustrating the configuration of the apparatus for atmospheric plasma surface treatment according to the embodiment of the present invention;

FIG. 4 is a diagram illustrating the usage of an apparatus for fabricating a disposable roasting pan according to an embodiment of the present invention;

FIG. 5 is a perspective view illustrating the winding of disposable roasting pans fabricated such that the surface of a base is surface-treated by atmospheric plasma according to an embodiment of the present invention;

FIG. 6 is a perspective view illustrating a sheet-shaped disposable roasting pan according to an embodiment of the present invention;

FIG. 7 is a perspective view illustrating a dish-shaped disposable roasting pan according to an embodiment of the present invention;

FIG. 8 is a view illustrating the usage of the sheet-shaped disposable roasting pan according to the embodiment of the present invention; and

FIG. 9 is a view illustrating the usage of the dish-shaped disposable roasting pan according to the embodiment of the present invention.

### DETAILED DESCRIPTION

Exemplary embodiments of the present invention will be described in detail below with reference to the accompanying drawings. In the following description of the embodiments of the present invention, the same components will be denoted by the same reference symbols throughout the drawings as much as possible, detailed descriptions of related well-known configurations and functions will be omitted in order to prevent the gist of the present invention from being made obscure, and the configurations illustrated in the accompanying drawings will be represented in the form of schematic diagrams for ease of description of the embodiments of the present invention, but may be different from actually implemented shapes.

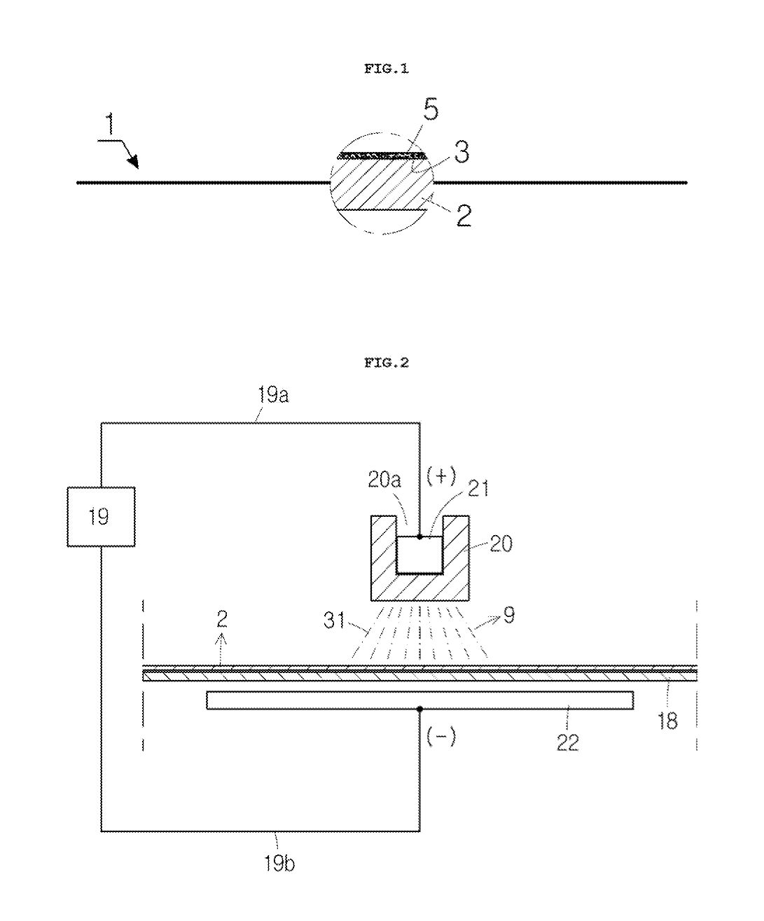

FIG. 1 is a sectional view illustrating a disposable roasting pan 1 according to an embodiment of the present invention. The disposable roasting pan 1 includes a base (roasting pan base) 2 formed of an aluminum sheet or aluminum foil; a surface-treated portion 3 configured such that a massive number of ultrafine depressions and protrusions having a size of about 10A are formed on the surface of the base 2 by atmospheric plasma; and a red clay ceramic layer 5 applied, dried and fixed onto the surface-treated portion 3 to a predetermined thickness.

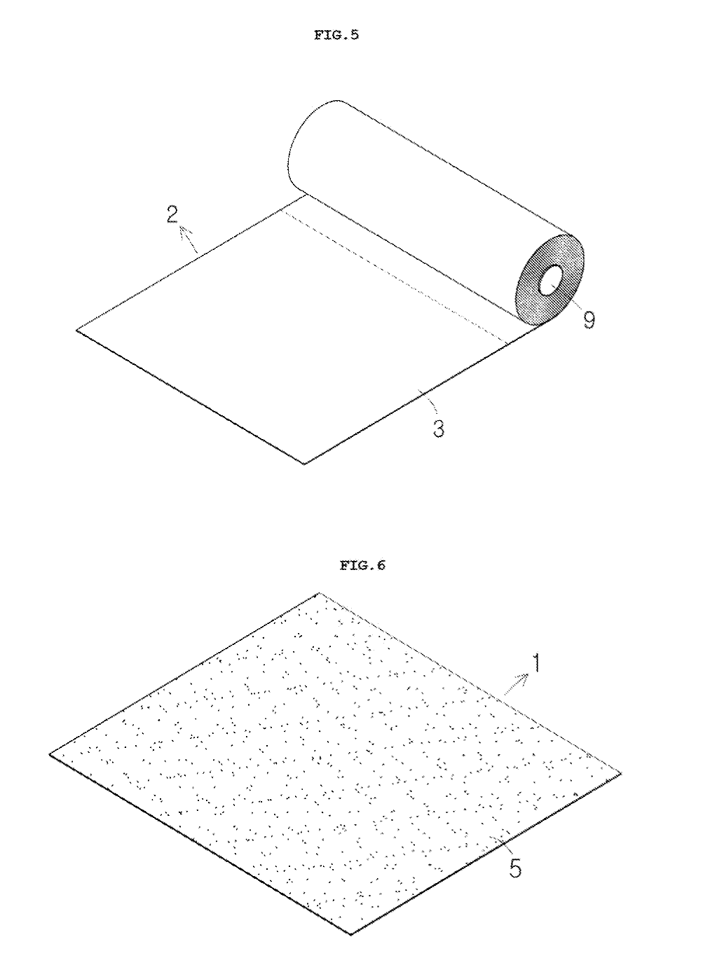

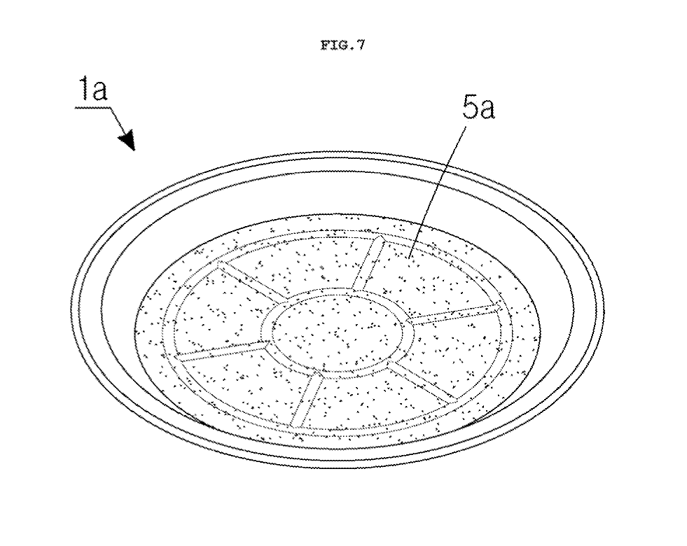

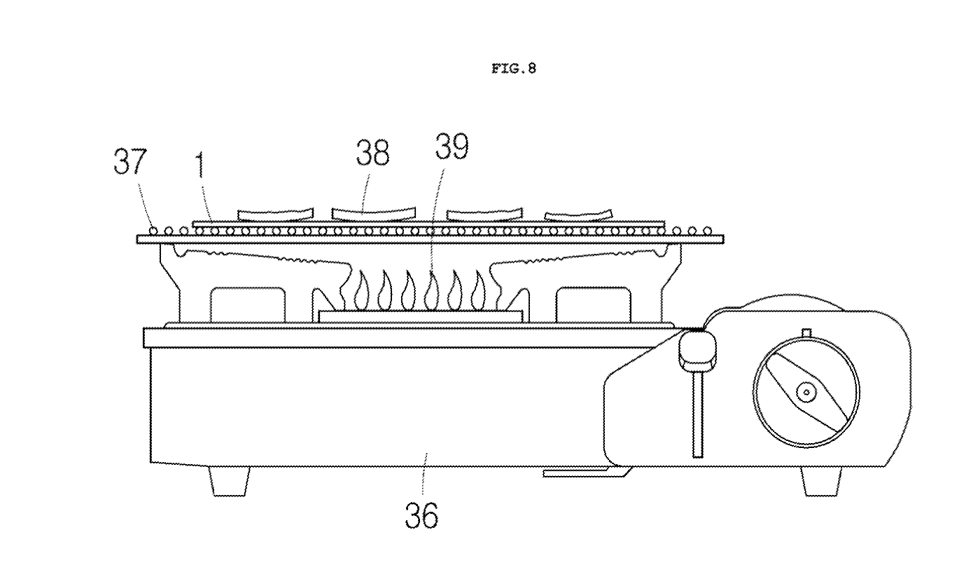

The disposable roasting pan 1 may be configured as a sheet-type structure of a predetermined size in which the surface thereof is coated, with the red clay ceramic layer 5, as illustrated in FIG. 6, or as an aluminum sheet dish 1a, as illustrated in FIG. 7. The base 2 is formed of an aluminum foil or aluminum sheet having a thickness ranging from 30 μm to 100 μm, which is widely used to hygienically wrap up food or other articles because it has a thin thickness.

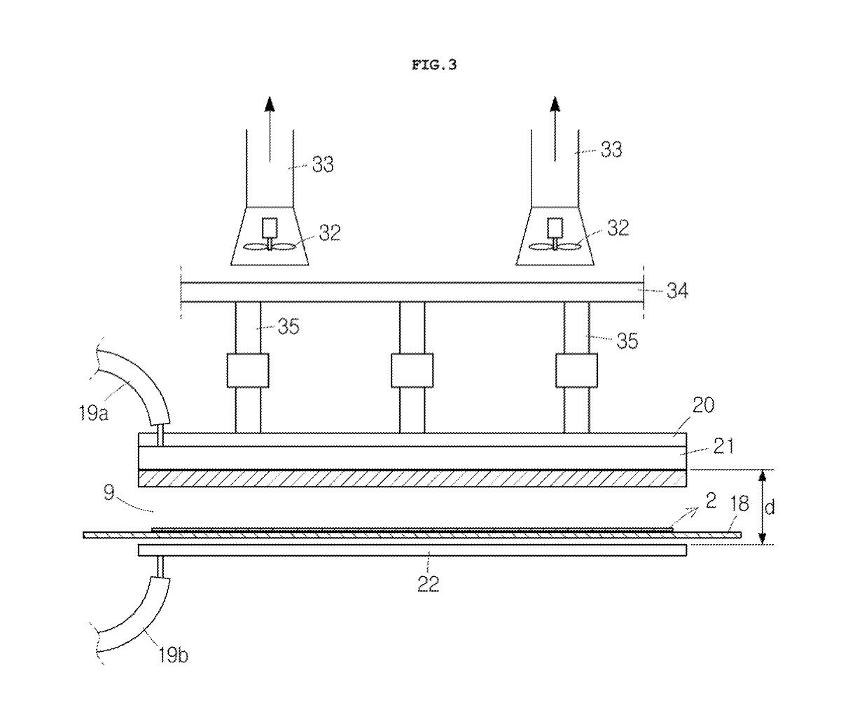

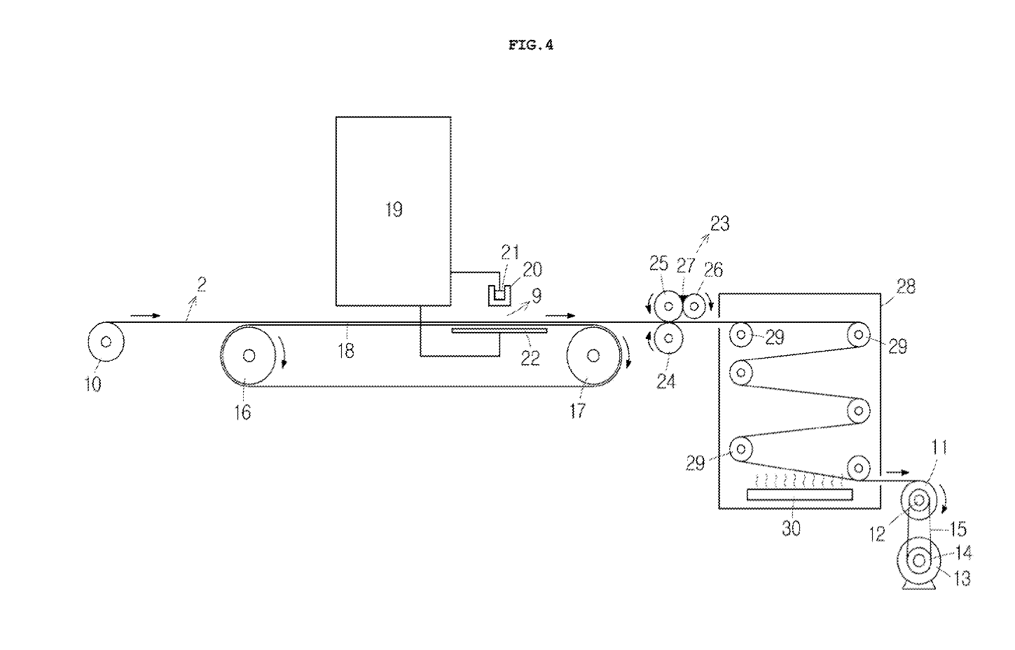

FIGS. 2 and 3 are diagrams illustrating the configuration of an apparatus for atmospheric plasma surface treatment according to an embodiment of the present invention. The apparatus for atmospheric plasma surface treatment includes a discharge electrode 21 disposed above a conveyer belt 18; a plate-shaped ground electrode 22 disposed below the conveyer belt 18; a power line 19a configured to apply the (+) high voltage of the high-voltage power unit 19 to the discharge electrode 21; a power line 19b configured to apply the (−) high voltage of the high-voltage power unit 19 to the ground electrode 22; and a discharge space 9 formed in a space between the discharge electrode 21 and the ground electrode 22 that are maintained at a predetermined, spaced distance “d.”

The discharge electrode 21 is fitted into and supported on an upwardly open groove 20a formed in the lengthwise direction of a ceramic support 20, and the ceramic support 20 is connected to and supported by a support member 34 by a plurality of insulating support rods 35. The support member 34 is connected and fastened to the support frame of the conveyer belt 18.

The ceramic support 20 may be used without a cooling device or cooling because of its high heat resisting property, and is advantageous to high-density discharge because of its high insulating and dielectric constants.

A high voltage applied across the discharge electrode 21 and the ground electrode 22 may range from 8,000 V to 50,0000 V, a frequency may range from 10,000 Hz to 50,000 Hz, and a current may range from 5 A to 10 A.

The discharge space 9 corresponds to a plasma generation space and a discharge space. An exhaust duct 32 provided with one or more exhaust fans 32 are installed above or beside the discharge space 9, and thus discharges gas and the like generated by an corona discharge to the air (the outside).

The principle of the surface treatment (reforming) of the base 2 according to the present invention is now described. Electrons are emitted in a direction from the ground electrode 22 to the discharge electrode 22 by a high voltage (an electric field) applied across the discharge electrode 21 and the ground electrode 22, are accelerated by the electric field and collide with ambient air molecules. In this case, when electrons having sufficient energy (tens to hundreds of eV) collide with air molecules within the discharge space 9, the air molecules are ionized and plasma is generated, in which case a separate discharge gas is not required because air around the discharge space 9 is used.

These electrons finally collide with a dielectric, for example, the base 2, between the discharge electrode 21 and the ground electrode 22, and thus charges the surface of the dielectric, in which case, if the energy of the colliding electrons is sufficient high (above tens of eV), the binding between surface molecules is removed and thus the surface particles are activated.

The surface molecules of the activated base 2 comes to have the property of being strongly combined with another material, for example, a red clay ceramic, because the surface molecules of the activated base 2 have an unstable molecular structure, and the surface molecules of the activated base 2 react with each other at a high speed and also react with the activated molecule surface because radicals in the plasma have high reactivity.

The above binding between the air radicals (plasma) and the activated molecules changes the molecular structure of the surface of the base 2, and the changed surface molecular structure is unstable compared to a molecular structure before the change. Accordingly, the property of being combined with the red clay ceramic becomes strong,

Through this process, the surface of the base 2 is activated, the surface molecular structure is changed, and surface tension is reduced. This surface tension can be adjusted by adjusting discharge voltage and the amount of discharge (a discharge period, a dielectric type, and a dielectric thickness).

In the present invention, to adjust the magnitude of the surface treatment of the base 2, a method of adjusting discharge voltage is most effect. However, if discharge voltage is excessively high, strong streamer corona is generated and may seriously damage the surface of the base 2, Accordingly, a massive number of desired ultrafine depressions and protrusions are formed without seriously damaging the surface-treated portion 3 of the base 3 by adjusting the spaced distance “d” between the discharge electrode 21 and the ground electrode 22 or by appropriately adjusting the discharge voltage and the discharge period.

That is, ultrafine depressions and protrusions having a size of about 10 Å are formed on the base surface-treated portion 3 formed of an aluminum sheet or aluminum foil by atmospheric plasma, and then a red clay ceramic liquid is firmly applied and fixed to a predetermined thickness, thereby forming the disposable roasting pan 1. The disposable roasting pan 1 is hygienic, does not require washing and also can be conveniently discarded because it is disposable and thus can be conveniently processed after usage, has a low production cost, and is used such that meat does not stick or is not burnt, the meat is not dehydrated, the texture of the meat is soft, and thus the unique flavor (savory taste and smell and the like) of the meat can be enjoyed because the meat is cooked by the action of far-infrared radiation.

FIG. 4 is a diagram illustrating the usage of an apparatus for fabricating a disposable roasting pan according to an embodiment of the present invention. The setup of the apparatus for atmospheric plasma surface treatment includes the base 2 wound around a pull-out roller 10 located on one side (entrance side) of the atmospheric plasma discharge space 9, a take-up roller 11 located on the other side (exit side) of the discharge space 9 and configured to wind the base 2, a pulley 12 mounted around the shaft of the take-up roller 11, a pulley 14 mounted around the axis of rotation of a drive motor 13 and the belt 15 configured to connect the two pulleys 12 and 14. In this setup, the take-up roller 11 is rotated by the belt 15 in the clockwise direction of FIG. 4. Accordingly, the base 2 wound around the pull-out roller 10 is drawn, is transferred to the take-up roller 11 through the discharge space 9, and is wound around the take-up roller 11. The base 2 is formed of an aluminum foil or aluminum sheet having a thickness ranging from 30 to 100 μm.

A conveyer belt 18 that is rotated in a single direction by a drive means (not illustrated) and both sides rollers 16 and 17 is installed between the pull-out roller 10 and the take-up roller 11, so that the base 2 is transferred in a discharge direction in a manner of being in contact with the upper surface of the conveyer belt 18. The apparatus for atmospheric plasma surface treatment illustrated in FIGS. 2 and 3 is installed at about the center of the conveyer belt 18, so that the surface-treated portion 3 of the base 2 is treated.

A coating unit 23, for example, a roller coating unit, is installed in the back portion of the apparatus for atmospheric plasma surface treatment. The coating unit 23 includes a lower drum 24 configured to support the bottom of the base 2; a coating drum 25 configured to apply a red clay ceramic liquid 27 while supporting the top of the base 2; an auxiliary drum 26 configured to operate while being in contact with the coating drum 25; and the red clay ceramic liquid 27 configured to be supplied into an upper space between the coating drum 25 and the auxiliary drum 26.

The base 2 moves in a direction toward a drying room 28, and the coating roller 25 applies the red clay ceramic liquid 27 sticking to the surface thereof to the surface-treated the surface of the base 2 to a predetermined thickness while being rotated in a counterclockwise direction.

The red clay ceramic liquid 27 is appropriately supplied between the coating drum 25 and the auxiliary drum 26 by a constant quantity supply means (not illustrated) and is maintained a predetermined height, so that the red clay ceramic liquid 27 is not completely consumed.

The base 3 coated with the red clay ceramic liquid 27 is dried while passing through the drying room 28 located between the back end of the coating unit 23 and the take-up roller 11. A plurality of guide rollers disposed in a vertical direction in a zigzag manner, or a plurality of guide roller 29 disposed in a lateral direction in a zigzag manner are installed inside the drying room 28.

An entrance and an exit through which the base 2 surface-treated by atmospheric plasma enters and exits are formed on both sides of the drying room 28. Heat or hot air having a temperature of 150° C. that is required for drying is generated in the low portion of the drying room 28 by the heating means 30 and/or the heating means 30 and the air blower means in which a constant temperature is maintained by a temperature detector and an electric heater, and thus the red clay ceramic liquid with which the surface-treated portion 3 of the base 2 is coated is dried and fixed. In the drying room 28, the moving distance and drying time of the base 3 are increased by the plurality of guide rollers 29 disposed in a zigzag manner.

The present invention is configured to use a dry-type method using atmospheric plasma, instead of a conventional wet-type method using steam, which has a lengthy, complicated and considerably low-productivity process, thereby resulting in a considerably simplified process, excellent coating efficiency, and significantly improved productivity.

A process of treating the surface of the base 2 of the disposable roasting pan I using atmospheric plasma and then forming the subsequent red clay ceramic layer 5 according to an embodiment of the present invention is described as follows:

1. Forming Ultrafine Depressions and Protrusions on Surface of Base

As illustrated in FIG. 4, The setup of the apparatus for atmospheric plasma surface treatment includes the bass 2 wound around a pull-out roller 10 located on one side (entrance side) of the atmospheric plasma discharge space 9, a take-up roller 11 located on the other side (exit side) of the discharge space 9 and configured to wind the base 2, a pulley 12 mounted around the shaft of the take-up roller 11, a pulley 14 mounted around the axis of rotation of a drive motor 13 and the belt 15 configured to connect the two pulleys 12 and 14. In this setup, the take-up roller 11 is rotated by the belt IS in the clockwise direction of FIG. 4. Accordingly, the base 2 wound around the pull-out roller 10 is drawn, is transferred to the take-up roller 11 through the discharge space 9, and is wound around the take-up roller 11. The base 2 is formed of an aluminum foil or aluminum sheet having a thickness ranging from 30 to 100 μm.

2. Coating Surface of Base with Red Clay Ceramic Liquid

A red clay ceramic liquid is prepared by mixing a red clay powder and a ceramic binder having a thickness of about 1 μm at a weight ratio of 50:50 and being diluted with water for general use (tap water) at a weight ratio of 50:50.

The red clay ceramic layer 5 having a thickness ranging from 10 to 20 part is formed by applying the red clay ceramic liquid to the surface-treated portion 3 of the base 2 on which the ultrafine depressions and protrusions having a size of about 10 Å have been formed by atmospheric plasma surface treatment using a method, such as roller coating, injection, spraying, transferring, or screen printing, as illustrated in FIG. 1. The application may be repeated a plurality of times until the red clay ceramic layer 5 reaches a desired thickness.

3. Drying

The red clay ceramic liquid is firmly fixed onto the surface of the base 2 and also the red clay ceramic layer 5 is formed by drying the base 2 coated with the red clay ceramic liquid using heat having a temperature of about 150° C. generated by the heating means 30 and/or the heating means 30 and an air blower means, disposed therebelow, for 10 to 30 minutes while transferring the base 2 along the plurality of rollers 29 disposed in the drying room 28 in a zigzag manner, as illustrated in FIGS. 6 and 7. As a result, the disposable roasting pan 1 is completed. A plurality of sheets of disposable roasting pans 1 may be packaged, distributed and used.

FIG. 7 is a perspective view illustrating a dish-shaped disposable roasting pan according to an embodiment of the present invention. The dish-shaped disposable roasting pan is configured such that a rim is formed around the upper edge of a body and a red clay ceramic-coated layer 5a having a thickness ranging from 10 to 20 μm is fixed onto the surface-treated portion of the aluminum sheet dish 1a surface-treated by atmospheric plasma by applying a red clay ceramic coating liquid to the surface-treated portion of the aluminum sheet dish 1a and then, drying it.

In the present invention, the base 2 may be cut into a predetermined size before applying a red clay ceramic liquid as described above, the red clay ceramic liquid may be applied and dried, and then a completed disposable roasting pan may be used. Alternatively, the red clay ceramic layer 5 having a thickness ranging from 10 to 20 μmay be applied and fixed onto the base 2 and then the base 2 may be cut and used.

4. Cutting and processing

As illustrated in FIG. 6, the base 2 may be cut into a size of, for example, 300 mm×300 mm, 300 mm×400 mm, or 400 m×400 mm by drawing the base 2 through the take-up roller 11 provided with a processing part so that it can be conveniently used. Alternatively, the base 2 may be cut and processed into a predetermined sized circular, or oval, polygonal shape, or other variations, and then may be used and commercialized as disposable roasting pans.

5. Usage

The disposable roasting pan 1 is used in such a way as to place the disposable roasting pan 1 coated with the red clay ceramic layer 5 and cut into a predetermined size on a grill 37 or a wire net installed above a cooking stove, such as a gas stove 36, as illustrated in FIG. 3, put meat 38 on the disposable roasting pan 1, and roast the meat 38 by heating it or cooking the meat 38 with various types of food placed thereon. The disposable roasting pan 1 is prevented from being bent downward by the support of the grill 37.

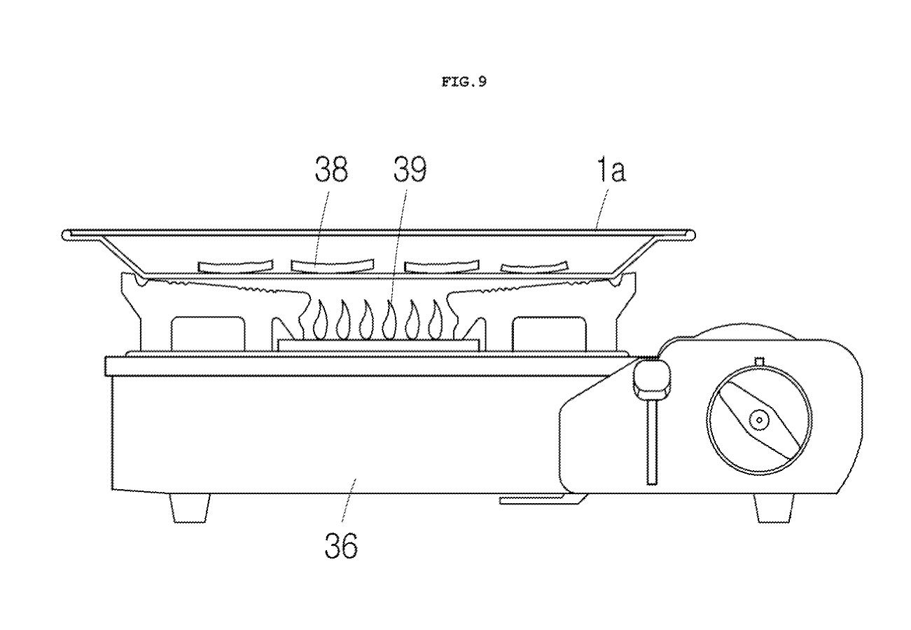

Furthermore, the aluminum sheet dish 1a onto which the red clay ceramic layer 5a has been fixed may be used directly on the gas stove 36 without requiring the grill 37, as illustrated in FIG. 9.

In the present invention, the red clay ceramic layer 5 is applied and fixed onto the front or one-side surface of the base 2 or the back or other-side surface of the base 2 is not processed. Accordingly, even when the disposable roasting pan is discarded after use, it is completely dissolved after a period ranging from a few months to 1 or 2 years by corrosion (oxidation), thus being environmentally friendly.

In the present invention, the thickness of the base 2 ranges from 30 to 100 μm. In the case where the disposable roasting pan is used in an outdoor environment in which it is exposed directly to flames, the thickness of the base 2 is preferably thick, for example, in the range from 50 to 100 μm, in order to prevent the disposable roasting pan from being bent downward. In contrast, in the case where the disposable roasting pan is used indoors in the state of being placed on the roasting pan of a roaster, the thickness of the base 2 is preferably thin, for example, in the range from 30 to 60 μm so that the disposable roasting pan comes into close contact with the surface of the roasting pan of the roaster and thus thermal conductivity is improved, since when the thickness of the base 2 is excessively thick, the disposable roasting pan cannot come into close contact with the surface of the roasting pan of the roaster and thus thermal conductivity is low.

The present invention is advantageous in that a process is simplified and thus productivity is significantly improved because a dry-type method using atmospheric plasma is employed instead of a conventional wet-type method using steam, and the red clay ceramic layer can foe very efficiently and easily applied because ultrafine depressions and protrusions are formed on the surface-treated portion of the base by atmospheric plasma and then the red clay ceramic layer is formed through coating.

The present invention is advantageous in that the disposable roasting pan can be conveniently used in not only an indoor environment and a restaurant but also an outdoor environment because the disposable roasting pan can be carried and used in a disposable manner, and the disposable roasting pan is hygienic, does not require washing and can be conveniently processed, because it is disposable and can be discarded after usage.

The present invention is advantageous in that the disposable roasting pan can be used such that meat does not stick or is not burnt, the meat is not dehydrated, the texture of the meat is soft arid thus the unique flavor of the meat can be enjoyed because the meat is cooked by the action of far-infrared radiation.

The present invention is advantageous in that a fabrication cost is reduced because the configuration of the disposable roasting pan is simple and the disposable roasting pan is environmentally friendly because the disposable roasting pan is rapidly oxidized when it is discarded after usage.

Although the present invention has been described in conjunction with limited embodiments and diagrams, the present invention is not limited to these embodiments, but it will be apparent to those skilled in the art that various modifications and variations can be made from the above description. Therefore, the scope of the present invention should be defined based on not only the attached claims but also equivalents to the claims, not only based on the described embodiments.

What is claimed is:

1. A method for surface treatment of a disposable roasting pan using atmospheric plasma, the method comprising the steps of:
(a) preparing an aluminum sheet base having a thickness ranging from 30 to 100 μm;
(b) forming fine depressions and protrusions on a surface of the aluminum sheet base by surface-treating the surface of the aluminum sheet base using atmospheric plasma;
(c) coating the surface of the base on which the fine depressions and protrusions have been formed with a red clay ceramic liquid in which a red clay powder and a ceramic binder have been mixed together;
(d)drying the base coated with the red clay ceramic liquid with hot air having a temperature of about 150° C. for a period ranging from 10 to 30 minutes.

2. The method of claim 1, wherein the fine depressions and protrusions formed at step (b) are ultrafine depressions and protrusions having a size of about 10 Å.

3. The method of claim 1, wherein the red clay ceramic liquid used at step (c) is formed by mixing the red clay powder and the ceramic binder having a thickness of about 1 μm at a weight ratio of 50:50 and then diluting the mixture with water for general use at a weight ratio of 50:50.

4. The method of claim 1, wherein the red clay ceramic liquid used at step (c) is applied to the surface of the base on which the fine depressions and protrusions have been formed to a thickness ranging from 10 to 20 μm.

5. A disposable roasting pan fabricated by the method for surface treatment of a disposable roasting pan set forth in claim 1.

6. An apparatus for surface treatment of a disposable roasting pan using atmospheric plasma, the apparatus comprising:
a conveyer belt configured to transfer an aluminum sheet base;
a discharge electrode disposed above the conveyer belt;
a plate-shaped ground electrode disposed below the conveyer belt;
a first power line configured to apply (+) high voltage of a high-voltage power unit to the discharge electrode;
a second power line configured to apply (−) high voltage of the high-voltage power unit to the ground electrode; and
a discharge space formed in a space between the discharge electrode and the ground electrode.

7. The apparatus of claim 6, wherein:
the discharge electrode is fitted into an upwardly open groove formed in a lengthwise direction of a ceramic support; and
the ceramic support is connected to a support member by a plurality of insulating support rods and is supported by the plurality of insulating support rods.

8. The apparatus of claim 6, wherein the high voltage applied across the discharge electrode and the ground electrode ranges from 8,000 V to 50,0000 V, a frequency ranges from 10,000 Hz to 50,000 Hz, and a current ranges from 5 A to 10 A.

9. The apparatus of claim 6, further comprising an exhaust duct disposed in any one of an upper portion and a side portion of the discharge space and equipped with at last one exhaust fan.

10. An apparatus for fabricating a disposable roasting pan, the apparatus comprising:
a base wound around a pull-out roller located on one side of the apparatus;
a take-up roller located on a remaining side of the apparatus, and configured to wind the base;
a pulley disposed around the take-up roller;
a pulley disposed around an axis of rotation of a drive motor;
a belt configured to connect the two pulleys;
a conveyer belt disposed between the pull-out roller and the take-up roller;
an apparatus for atmospheric plasma surface treatment disposed above the conveyer belt;
a coating unit located behind the apparatus for atmospheric plasma surface treatment; and
a drying room located between the coating unit and the take-up roller.

11. The apparatus of claim 10, wherein the coating unit comprises:
a lower drum configured to support a bottom of the base;
a coating drum configured to support a top of the base and to apply a red clay ceramic liquid;
an auxiliary drum configured to operate in contact with the coating drum; and
the red clay ceramic liquid configured to be supplied into a space above an interval between the coating drum and the auxiliary drum.

12. The apparatus of claim 10, wherein the drying room comprises:
a plurality of guide rollers disposed inside the drying room in a zigzag manner;
heating means disposed in a lower portion of the drying room so that a temperature of about 150° C. is constantly maintained; and
an entrance and an exit formed on both sides of the drying room.

13. A disposable roasting pan fabricated by a method for surface treatment using atmospheric plasma, the disposable roasting pan comprising:
an aluminum sheet base having a thickness ranging from 30 to 100 μm;
a surface-treated portion configured such that fine depressions and protrusions having a size of about 10 Å are formed on a surface of the aluminum sheet base by atmospheric plasma; and
a red clay ceramic layer applied, dried and fixed onto the surface-treated portion to a thickness ranging from 10 to 20 μm.

14. The disposable roasting pan of claim 13, wherein the aluminum sheet base is of a dish type.
